(19) United States
(12) Patent Application Publication
(10) Pub. No.: US 2025/0378897 A1
(43) Pub. Date: Dec. 11, 2025

(54) MEMORY DEVICE HAVING REDUCED AREA

(71) Applicant: Samsung Electronics Co., Ltd., Suwon-si (KR)

(72) Inventor: Daeshik Kim, Suwon-si (KR)

(21) Appl. No.: 18/929,849

(22) Filed: Oct. 29, 2024

(30) Foreign Application Priority Data
Jun. 7, 2024 (KR) 10-2024-0074529

(51) Int. Cl. G11C 17/18; G11C 17/16

(52) U.S. Cl. CPC G11C 17/18; G11C 17/16

(57) ABSTRACT

Disclosed is a memory device which includes a plurality of memory cells, word lines electrically connected to rows of the plurality of memory cells, and bit lines and source lines electrically connected with columns of the plurality of memory cells. The plurality of memory cells include main memory cells of a main cell area that are configured to support a read operation and a write operation, and one time program cells of a one time program (OTP) cell area that are configured to support the write operation once and a one time program reference cell for the read operation of the one time program cells. Each of the main memory cells is electrically connected to a respective word line, and each of the one time program cells is electrically connected to at least two respective word lines of the word lines.

### CROSS-REFERENCE TO RELATED APPLICATIONS

This application claims priority under 35 U.S.C. § 119 to Korean Patent Application No. 10-2024-0074529 filed on Jun. 7, 2024, in the Korean Intellectual Property Office, the disclosures of which are incorporated by reference herein in their entireties.

### BACKGROUND

Embodiments of the present disclosure described herein relate to an electronic device, and more particularly, relate to a memory device with the reduced area.

A nonvolatile memory device may be implemented in various forms like a phase-change memory device, a ferroelectric memory device, a magnetic memory device, a resistive memory device, etc. The nonvolatile memory device supports a random access and thus is utilized in various fields requiring the random access and a nonvolatile characteristic.

One of the main characteristics desired of an electronic device including the nonvolatile memory device is low power consumption. Accordingly, the nonvolatile memory device may also need to operate with low power consumption.

Another of the main characteristics desired of the electronic device including the nonvolatile memory device is the smaller area. Accordingly, the nonvolatile memory device may also need to have the reduced area.

The nonvolatile memory device may include a memory cell array including nonvolatile memory cells and a one-time program (OTP) cell array including OTP cells. Implementing the memory cell array and the OTP cell array separately may cause an increase in power consumption of the nonvolatile memory device and an increase in the area of the nonvolatile memory device.

### SUMMARY

Embodiments of the present disclosure provide a nonvolatile memory device capable of reducing power consumption with the reduced area.

According to some embodiments, a memory device includes a plurality of memory cells, word lines electrically connected to rows of the plurality of memory cells, and bit lines and source lines electrically connected with columns of the plurality of memory cells. The plurality of memory cells include main memory cells of a main cell area that are configured to support a read operation and a write operation, one time program cells of a one time program (OTP) cell area that are configured to support the write operation once, and a one time program reference cell for the read operation of the one time program cells. Each of the main memory cells is electrically connected to a respective word line of the word lines, and each of the one time program cells is electrically connected to at least two respective word lines of the word lines.

According to some embodiments, a memory device includes a plurality of memory cells, word lines electrically connected to rows of the plurality of memory cells, and bit lines and source lines electrically connected with columns of the plurality of memory cells. The plurality of memory cells include main memory cells of a main cell area that are configured to support a read operation and a write operation, one time program cells of a one time program (OTP) cell area that are configured to support the write operation once, a reference resistor electrically connected to a reference bit line and having a fixed resistance value for the read operation of the main memory cells and the one time program cells, and a sense amplifier applying a first voltage to a reference source line during the read operation of the main memory cells and configured to apply a second voltage different from the first voltage to the reference source line during the write operation of the one time program cells.

According to some embodiments, a memory device includes a plurality of memory cells, word lines electrically connected to rows of the plurality of memory cells, and bit lines and source lines electrically connected with columns of the plurality of memory cells. The plurality of memory cells include main memory cells of a main cell area that are configured to support a read operation and a write operation, one time program cells of a one time program (OTP) cell area that are configured to support the write operation once, a reference resistor having a fixed first resistance value for the read operation of the main memory cells, a one time program reference resistor having a fixed second resistance value for the read operation of the one time program cells, and a switch that electrically connects the reference resistor to a reference bit line during the read operation of the main memory cells and electrically connects the one time program reference resistor to the reference bit line during the read operation of the one time program cells.

### BRIEF DESCRIPTION OF THE FIGURES

The above and other objects and features of the present disclosure will become apparent by describing in detail embodiments thereof with reference to the accompanying drawings.

FIG. 1 illustrates a nonvolatile memory device according to some embodiments of the present disclosure.

FIG. 2 illustrates a memory cell array according to some embodiments of the present disclosure.

FIG. 3 illustrates an example of a main cell array of FIG. 2.

FIG. 4 illustrates an example of an OTP cell area of FIG. 2.

FIG. 5 is a diagram illustrating some components emphasized to describe some embodiments of the present disclosure easily, in an OTP cell area of FIG. 4.

FIG. 6 illustrates distributions of resistance values of main memory cells, OTP cells, reference cells, and an OTP reference cell according to some embodiments of the present disclosure.

FIG. 7 illustrates an example of wires associated with a main memory cell.

FIG. 8 illustrates an example of wires associated with an OTP cell according to some embodiments of the present disclosure.

FIG. 9 illustrates an example of wires associated with a reference cell according to some embodiments of the present disclosure.

FIG. 10 illustrates an example of wires associated with an OTP reference cell according to some embodiments of the present disclosure.

FIG. 11 illustrates a memory cell array according to some embodiments of the present disclosure.

FIG. 12 illustrates an example of an OTP cell area of FIG. 11.

FIG. 13 illustrates a memory cell array according to some embodiments of the present disclosure.

FIG. 14 illustrates an example of an OTP cell area of FIG. 13.

FIG. 15 illustrates an example of wires associated with a dummy cell according to some embodiments of the present disclosure.

FIG. 16 illustrates a memory cell array according to some embodiments of the present disclosure.

FIG. 17 illustrates a memory cell array according to some embodiments of the present disclosure.

FIG. 18 illustrates an operating method of a nonvolatile memory device according to some embodiments of the present disclosure.

FIG. 19 is a diagram of a system to which a storage device is applied, according to some embodiments.

### DETAILED DESCRIPTION

Below, embodiments of the present disclosure will be described in detail and clearly to such an extent that an ordinary one in the art easily carries out the present disclosure.

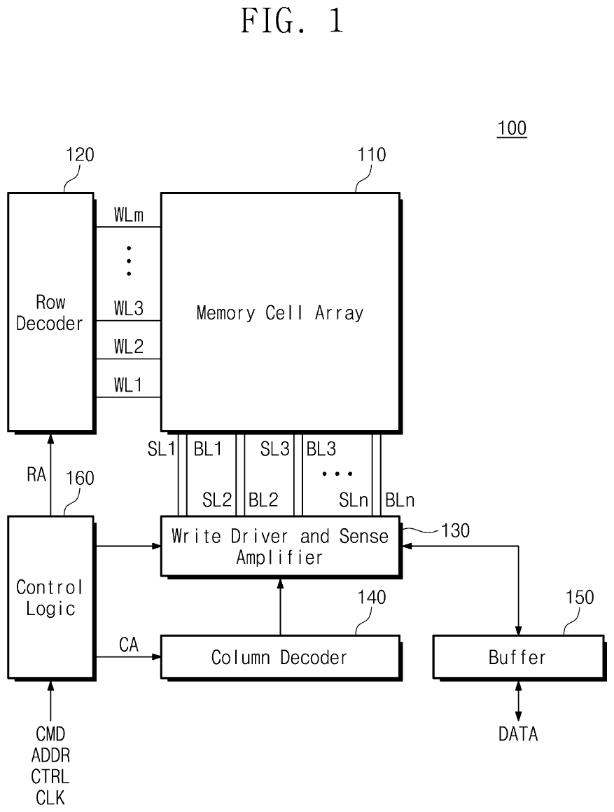

FIG. 1 illustrates a nonvolatile memory device 100 according to some embodiments of the present disclosure. Referring to FIG. 1, the nonvolatile memory device 100 may include a memory cell array 110, a row decoder 120, a write driver and sense amplifier 130, a column decoder 140, a buffer 150, and control logic 160.

The memory cell array 110, the row decoder 120, the write driver and sense amplifier 130, the column decoder 140, the buffer 150, and the control logic 160 may be implemented with hardware distinguished from each other. The memory cell array 110, the row decoder 120, the write driver and sense amplifier 130, the column decoder 140, the buffer 150, and the control logic 160 may be referred to in combination with various terms such as “circuit”, “block”, “unit”, etc.

The memory cell array 110 may include nonvolatile memory cells and one time program (OTP) cells arranged in rows and columns. For example, the nonvolatile memory cells and the OTP cells may include phase-change memory cells, ferroelectric memory cells, magnetic memory cells, or resistive memory cells. The rows of the nonvolatile memory cells and the rows of the OTP cells may be connected to first to m-th word lines WL1 to WLm. The columns of the nonvolatile memory cells may be connected to first to n-th bit lines BL1 to BLn and first to n-th source lines SL1 to SLn.

The row decoder 120 may be connected to the rows of the nonvolatile memory cells and the OTP cells of the memory cell array 110 through the first to m-th word lines WL1 to WLm. The row decoder 120 may receive a row address RA from the control logic 160. Based on the row address RA, the row decoder 120 may select one word line among the first to m-th word lines WL1 to WLm and may not select the remaining word lines thereof.

The row decoder 120 may apply a selection word line voltage to the selected word line and may apply a non-selection word line voltage to the unselected word lines (or may float the unselected word lines). For example, the level or voltage of the selection word line voltage and the level or voltage of the non-selection word line voltage may change depending on whether any of a first write operation (or a set operation), a second write operation (or a reset operation), or a read operation is performed.

The write driver and sense amplifier 130 may be electrically connected to the memory cell array 110, in particular, to the columns of the nonvolatile memory cells and the OTP cells through the first to n-th bit lines BL1 to BLn and the first to n-th source lines SL1 to SLn. For example, one bit line and one source line may be connected to one column of the nonvolatile memory cells or one column of the OTP cells.

The write driver and sense amplifier 130 may include write driver circuits, each of which corresponds to each of the first to n-th bit lines BL1 to BLn and each of the first to n-th source lines SL1 to SLn, and sense amplifier circuits, each of which corresponds to each of the first to n-th bit lines BL1 to BLn and each of the first to n-th source lines SL1 to SLn. The write driver and sense amplifier 130 may receive a column address CA from the control logic 160.

During the write operation, based on the column address CA, some of the write driver circuits may be activated, and the remaining write driver circuits and the sense amplifier circuits may be deactivated. Each of the activated write driver circuits may apply voltages for the write operation to the corresponding source line and the corresponding bit line. Each of the deactivated write driver circuits may apply voltages for inhibition of the write operation to the corresponding source line and/or the corresponding bit line or may float the corresponding source line and/or the corresponding bit line.

During the read operation, based on the column address CA, some of the sense amplifier circuits may be activated, and the remaining sense amplifier circuits and the write driver circuits may be deactivated. Each of the activated sense amplifier circuits may apply voltages for the read operation to the corresponding source line and the corresponding bit line. Each of the deactivated sense amplifier circuits may apply voltages for inhibition of the read operation to the corresponding source line and/or the corresponding bit line or may float the corresponding source line and/or the corresponding bit line.

Some embodiments in which the write driver and sense amplifier 130 is connected to the memory cell array 110 through the first to n-th bit lines BL1 to BLn and the first to n-th source lines SL1 to SLn is illustrated. However, the first to n-th bit lines BL1 to BLn or the first to n-th source lines SL1 to SLn may be omitted. That is, one column of nonvolatile memory cells of the memory cell array 110 may be electrically connected to one line (e.g., a bit line or a source line).

The column decoder 140 may perform a switching operation between the write driver and sense amplifier 130 and the buffer 150 and/or between the write driver and sense amplifier 130 and the memory cell array 110. The column decoder 140 may receive the column address CA from the control logic 160. The column decoder 140 may perform the switching operation based on the column address CA such that the activated write driver circuits or the activated sense amplifier circuits are electrically connected to the buffer 150, and/or the column decoder 140 may perform the switching operation based on the column address CA such that the activated write driver circuits or the activated sense amplifier circuits are electrically connected to the corresponding bit lines and the corresponding source lines.

The buffer 150 may exchange data with an external device and may exchange data with the write driver and sense amplifier 130. The buffer 150 may transfer the data received from the external device to the activated write driver circuits of the write driver and sense amplifier 130. The buffer 150 may transfer the data sensed by the activated sense amplifier circuits to the external device.

The control logic 160 may receive a command CMD, an address ADDR, a control signal CTRL, and a clock signal CLK from the external device. The command CMD and the address ADDR may be received in order of the command CMD and the address ADDR or in order of the address ADDR and the command CMD. In some embodiments, the command CMD and the address ADDR may be simultaneously received.

The command CMD may include a write command and a read command. The write command may cause one of the first write (or set) operation and/or the second write (or reset) operation or all thereof. In response to the command CMD, the control logic 160 may control the row decoder 120, the write driver and sense amplifier 130, the column decoder 140, and the buffer 150 such that the write operation or the read operation is performed. The write operation may include one of the first write (or set) operation and/or the second write (or reset) operation or both operations.

The address ADDR may include the row address RA and the column address CA. The control logic 160 may transfer the row address RA to the row decoder 120 and may transfer the column address CA to the write driver and sense amplifier 130 and to the column decoder 140.

The control signal CTRL may include various signals which are used to control the nonvolatile memory device 100. For example, some of the signals included in the control signal CTRL may be bidirectional signals and may be used to notify the external device of the status of the nonvolatile memory device 100.

The clock signal CLK may be used to synchronize the operation of the nonvolatile memory device 100 and the operation of the external device. The nonvolatile memory device 100 may interact with the external device in synchronization with the clock signal CLK. For example, the nonvolatile memory device 100 may exchange the command CMD, the address ADDR, the control signal CTRL, or data “DATA” with the external device in synchronization with the clock signal CLK.

In some embodiments, the control logic 160 may generate an internal clock signal of a high frequency by multiplying the frequency of the clock signal CLK. The control logic 160 may control the row decoder 120, the write driver and sense amplifier 130, the column decoder 140, and the buffer 150, based on the internal clock signal. For example, the control logic 160 may control operation timings, switching timings, etc. of the row decoder 120, the write driver and sense amplifier 130, the column decoder 140, and the buffer 150, based on the internal clock signal.

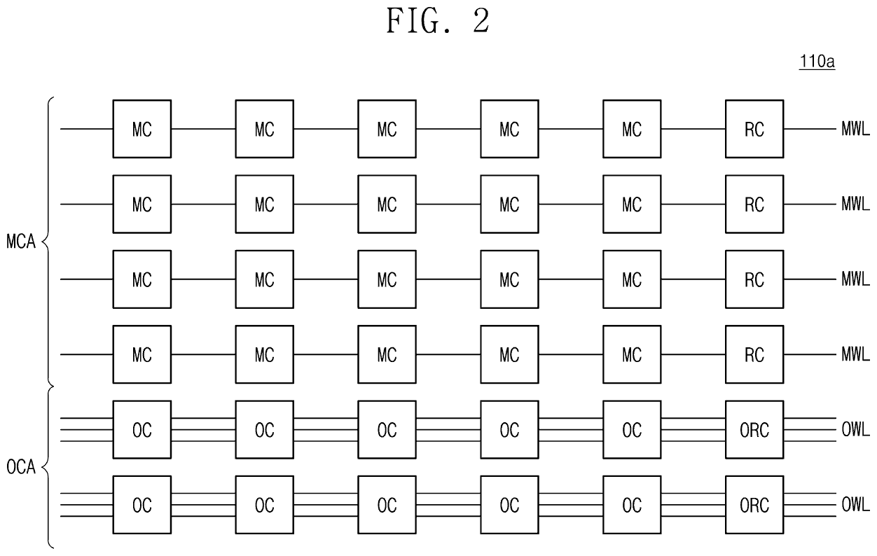

FIG. 2 illustrates a memory cell array 110a according to some embodiments of the present disclosure. Referring to FIGS. 1 and 2, the memory cell array 110a may include a main cell area MCA and an OTP cell area OCA. The main cell area MCA may include main memory cells MC and reference cells RC arranged in rows and columns. The main memory cells MC may be used to write data received from a host device or to read the written data. One row of the main memory cells MC may be electrically connected to one main word line MWL. The reference cell RC may be used to read the main memory cells MC of the main cell area MCA. The reference cells RC may be electrically connected to one main word line MWL. A resistance value of the reference cell RC may be different from resistance values of the main memory cells MC.

The OTP cell area OCA may include OTP cells OC and OTP reference cells ORC arranged in rows and columns. The OTP cells OC may be cells which are permitted such that the write operation is performed only once and such that the read operation is performed plural times. The OTP cells OC may be used to store secure data such as a serial number of the nonvolatile memory device 100. In some embodiments, a resistance value of the OTP cell OC programmed once may be different from resistance values of the main memory cells MC and the reference cells RC.

In some embodiments, the reference cells RC and the OTP reference cells ORC may be located at the same column. The OTP cells OC and the OTP reference cell ORC belonging to one row may be electrically connected to three OTP word lines OWL. However, the number of OTP word lines OWL electrically connected to the OTP cells OC and the OTP reference cells ORC belonging to one row is plural, but the present disclosure is not limited thereto.

The first to m-th word lines WL1 to WLm described with reference to FIG. 1 may include the main word lines MWL and the OTP word lines OWL of FIG. 2.

In some embodiments, compared to FIG. 1, the first to n-th source lines SL1 to SLn and the first to n-th bit lines BL1 to BLn are omitted to prevent a drawing from being unnecessarily complicated. Memory cells which belong to one column and include the main memory cells MC, the OTP cells OC, the reference cell RC, or the OTP reference cell ORC of the memory cell array 110a may be electrically connected in common to one source line and one bit line.

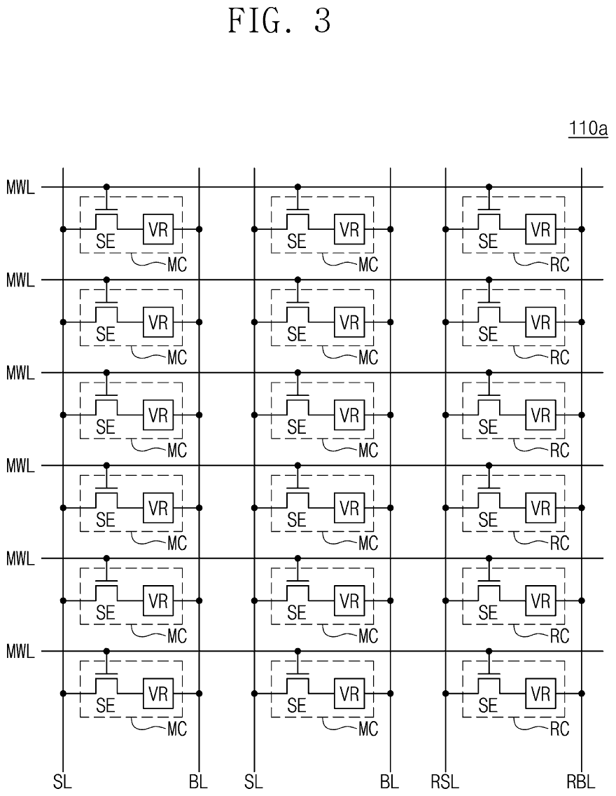

FIG. 3 illustrates an example of the main cell area MCA of FIG. 2. Referring to FIGS. 1, 2, and 3, each of the main memory cells MC and the reference cells RC may include a selection element SE and a variable resistance element VR. The selection element SE may include a first terminal electrically connected to a corresponding source line SL (or a reference source line RSL), a gate electrically connected to a corresponding main word line MWL, and a second terminal electrically connected to the variable resistance element VR. The variable resistance element VR may be electrically connected to the second terminal of the selection element SE and a corresponding bit line BL (or a reference bit line RBL).

The reference source line RSL and the reference bit line RBL may be similar or identical to the remaining source lines SL and the remaining bit lines BL in the main cell area MCA.

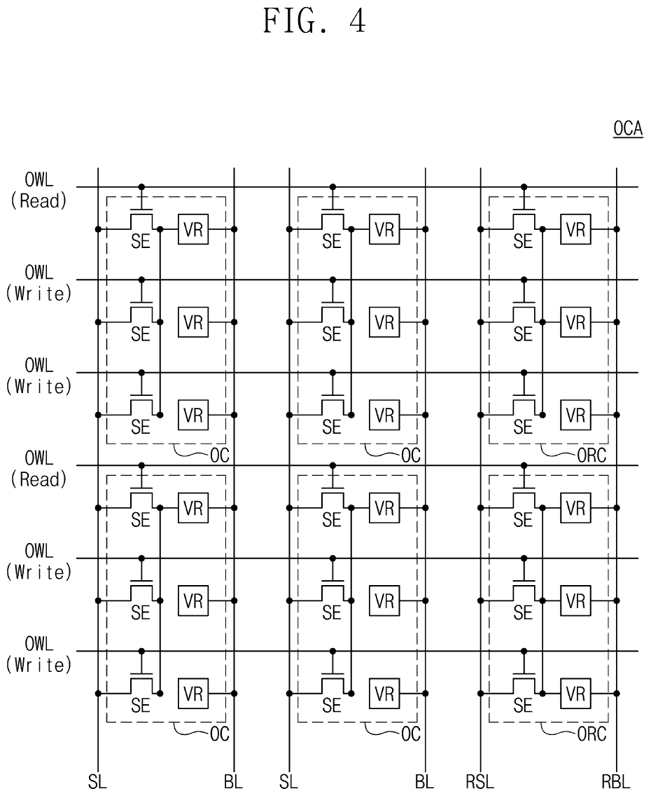

FIG. 4 illustrates an example of the OTP cell area OCA of FIG. 2. Referring to FIGS. 1, 2, 3, and 4, each of the OTP cells OC may include three selection elements SE and three variable resistance elements VR. The selection element SE belonging to the first row of each OTP cell OC may include a first terminal electrically connected to a corresponding source line SL, a gate electrically connected to a corresponding OTP word line OWL, and a second terminal electrically connected to a corresponding variable resistance element VR. Each variable resistance element VR may be electrically connected to the second terminal of the corresponding selection element SE and a corresponding bit line BL (or the reference bit line RBL).

Each of the selection elements SE belonging to the second row and the third row of each OTP cell OC may include a first terminal electrically connected to the corresponding source line SL, a gate electrically connected to a corresponding OTP word line OWL, and a second terminal floated. The variable resistance elements VR belonging to the second row and the third row of each OTP cell OC may be electrically connected to the bit line BL.

The structure of the selection element SE and the variable resistance element VR of the first row of each OTP cell OC may be the same as or similar to the structure of the main memory cells MC. The structure of the selection element SE and the variable resistance element VR of each of the second row and the third row of each OTP cell OC may be the same as or similar to the structure of the main memory cells MC except that the selection element SE and the variable resistance element VR are not connected.

In an embodiment, the OTP reference cell ORC may include three selection elements SE and three variable resistance elements VR. Each of the selection elements SE belonging to the first row and the second row of the reference cell RC may include a first terminal electrically connected to the reference source line RSL, a gate electrically connected to a corresponding OTP word line OWL, and a second terminal electrically connected to a corresponding variable resistance element VR. Each variable resistance element VR may be electrically connected to the second terminal of the corresponding selection element SE and the reference bit line RBL.

The selection element SE belonging to the third row of the reference cell RC may include a first terminal electrically connected to the reference source line RSL, a gate electrically connected to a corresponding OTP word line OWL, and a second terminal floated. The variable resistance element VR belonging to the third row of the OTP reference cell ORC may be electrically connected to the reference bit line RBL.

The structure of the selection element SE and the variable resistance element VR of each of the first and second rows of the reference cell RC may be the same as or similar to the structure of the main memory cell MC. The structure of the selection element SE and the variable resistance element VR of the third row of the reference cell RC may be the same as or similar to the structure of the main memory cells MC except that the selection element SE and the variable resistance element VR are not electrically connected.

In another embodiment, the OTP reference cell ORC may include three selection elements SE and three variable resistance elements VR. Each of the selection elements SE belonging to the first row, the second row, and the third row of the OTP reference cell ORC may include a first terminal electrically connected to the reference source line RSL, a gate electrically connected to a corresponding OTP word line OWL, and a second terminal electrically connected to a corresponding variable resistance element VR. Each variable resistance element VR may be electrically connected to the second terminal of the corresponding selection element SE and the reference bit line RBL.

The structure of the selection element SE and the variable resistance element VR of each row of the OTP reference cell ORC may be the same as or similar to the structure of the main memory cell MC.

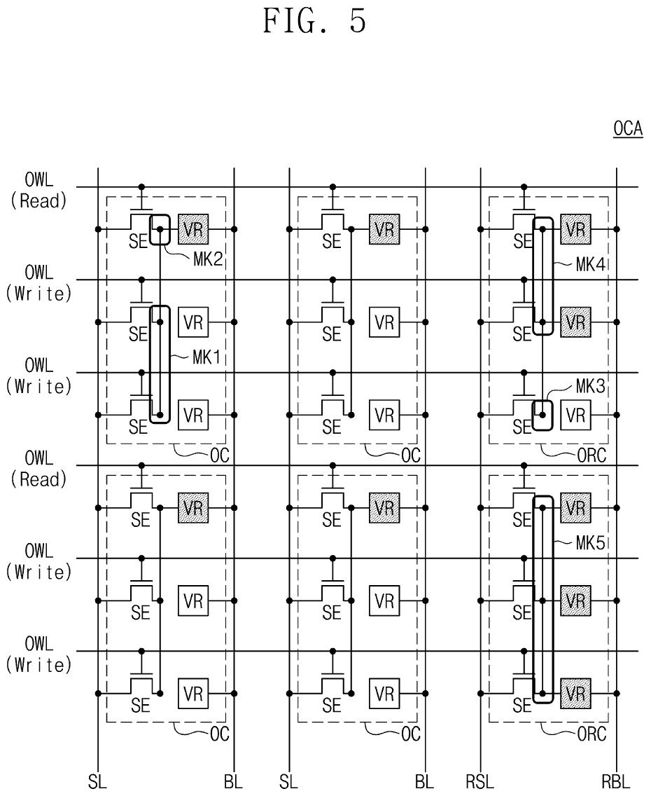

FIG. 5 is a diagram illustrating some components emphasized to describe some embodiments of the present disclosure easily, in the OTP cell area OCA of FIG. 4. Referring to FIGS. 1, 2, 3, 4, and 5, as illustrated by a first mark MK1 and a second mark MK2, in the OTP cell OC, the selection element SE of the first row may be electrically connected to the variable resistance element VR, and the selection elements SE of the second and third rows may not be electrically connected to the variable resistance elements VR. In some embodiments, in the OTP cell OC, the second terminals of the selection elements SE may be connected in common.

Voltages transferred to the three OTP word lines OWL may be transferred to the variable resistance element VR of the first row, which is shaded. The OTP word line OWL of the first row may be used for the read operation on the OTP cell OC, and the OTP word lines OWL of the second row and the third row may be used for the write operation on the OTP cells OC. However, in some embodiments of the present disclosure, one OTP word line OWL may be used for the read operation, and one or three OTP word lines may be used for the write operation.

As illustrated by a third mark MK3 and a fourth mark MK4, in the OTP reference cell ORC according to an embodiment, the selection elements SE of the first row and the second row may be electrically connected to the variable resistance elements VR, and the selection element SE of the third row may not be electrically connected to the variable resistance element VR. In some embodiments, in the OTP reference cell ORC, the second terminals of the selection elements SE may be connected in common.

Voltages transferred to the three OTP word lines OWL may be transferred to the variable resistance elements VR of the first row and the second row, all of which are shaded. The OTP word line OWL of the first row may be used for the read operation on the OTP reference cells ORC, and the OTP word lines OWL of the second row and the third row may be used for the write operation on the OTP reference cells ORC. However, in some embodiments of the present disclosure, one OTP word line OWL may be used for the read operation, and one or three OTP word lines may be used for the write operation.

As illustrated by a fifth mark MK5, in the OTP reference cell ORC according to another embodiment, the selection elements SE of the first row, the second row, and the third row are electrically connected to the variable resistance elements VR. In some embodiments, in the OTP reference cells ORC, the second terminals of the selection elements SE may be connected in common.

Voltages transferred to the three OTP word lines OWL may be transferred to the variable resistance elements VR of the first row, the second row, and the third row, all of which are shaded. The OTP word line OWL of the first row may be used for the read operation on the OTP reference cells ORC, and the OTP word lines OWL of the second row and the third row may be used for the write operation on the OTP reference cell ORC. However, in some embodiments of the present disclosure, one OTP word line OWL may be used for the read operation, and one or three OTP word lines may be used for the write operation.

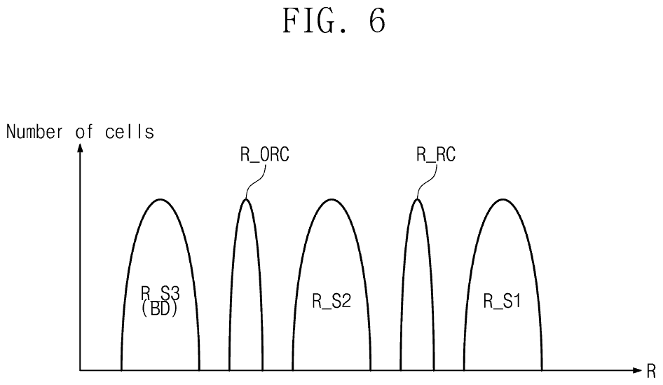

FIG. 6 illustrates distributions of resistance values of the main memory cells MC, the OTP cells OC, the reference cells RC, and the OTP reference cells ORC according to some embodiments of the present disclosure. In FIG. 6, the horizontal axis represents a resistance value “R”, and the vertical axis represents the number of cells.

Referring to FIGS. 3, 5, and 6, the main memory cells MC may have resistance values corresponding to a first state R_S1 and a second state R_S2. The first state R_S1 may correspond to a high-resistance state such as an anti-parallel state of an MTJ memory cell or an amorphous state of a phase-change memory cell. The second state R_S2 may correspond to a low-resistance state such as a parallel state of an MTJ memory cell or a crystalline state of a phase-change memory cell. As the variable resistance element VR of the main memory cell MC is programmed to have one of the first state R_S1 and the second state R_S2, the variable resistance element VR may store data. During the read operation, the main memory cell MC may provide a voltage or a current corresponding to a resistance of the corresponding state among the first state R_S1 and the second state R_S2.

The reference cells RC may have a reference state R_RC. The reference state R_RC may have a resistance value between the resistance value of the first state R_S1 and the resistance value of the second state R_S2. During the read operation, the reference state R_RC may provide a voltage or a current enabling distinguishing between the first state R_S1 and the second state R_S2.

The OTP cell OC may have a resistance value corresponding to a third state R_S3. For example, the third state R_S3 may be implemented by breaking down the variable resistance element VR (refer to “BD”). The OTP cell OC may include one valid variable resistance element VR (e.g., shaded). Because one variable resistance element VR is electrically connected to three OTP word lines OWL, the variable resistance element VR may be broken down easily by using a lower voltage so as to have the third state R_S3.

The OTP reference cell ORC may have an OTP reference state R_ORC. The OTP reference state R_ORC may have a resistance value between the resistance value of the third state R_S3 and the resistance value of the second state R_S2. During the read operation, the OTP reference state R_ORC may provide a voltage or a current enabling distinguishing between the third state R_S3 and the second state R_S2.

In some embodiments, each of two valid variable resistance elements VR (e.g., the variable resistance elements VR shaded) of the reference cell RC may be programmed to the first state R_S1. Between the two valid variable resistance elements VR of the OTP reference cell ORC are electrically connected in parallel between the reference source line RSL and the reference bit line RBL, a total resistance value of the OTP reference cell ORC may correspond to half the resistance value of the first state R_S1. The OTP reference state R_RC may be easily implemented by programming each of the valid variable resistance elements VR of the OTP reference cell ORC to the first state R_S1.

In some other embodiments, each of three valid variable resistance elements VR (e.g., the variable resistance elements VR shaded) of the OTP reference cell ORC may be programmed to the second state R_S2. Between the three valid variable resistance elements VR of the OTP reference cell ORC are electrically connected in parallel between the reference source line RSL and the reference bit line RBL, a total resistance value of OTP reference cell ORC may correspond to ⅓ of the resistance value of the second state R_S2. The OTP reference state R_ORC may be easily implemented by programming each of the valid variable resistance elements VR of the OTP reference cell ORC to the second state R_S2.

In some embodiments, the OTP reference cell ORC may be modified to have two valid variable resistance elements VR. In this case, the OTP reference cell ORC may have the same structure or similar structure as the reference cell RC, but valid variable resistance elements VR may be programmed to the second state R_S2. A total resistance value of the OTP reference cell ORC may be half the resistance value of the second state R_S2.

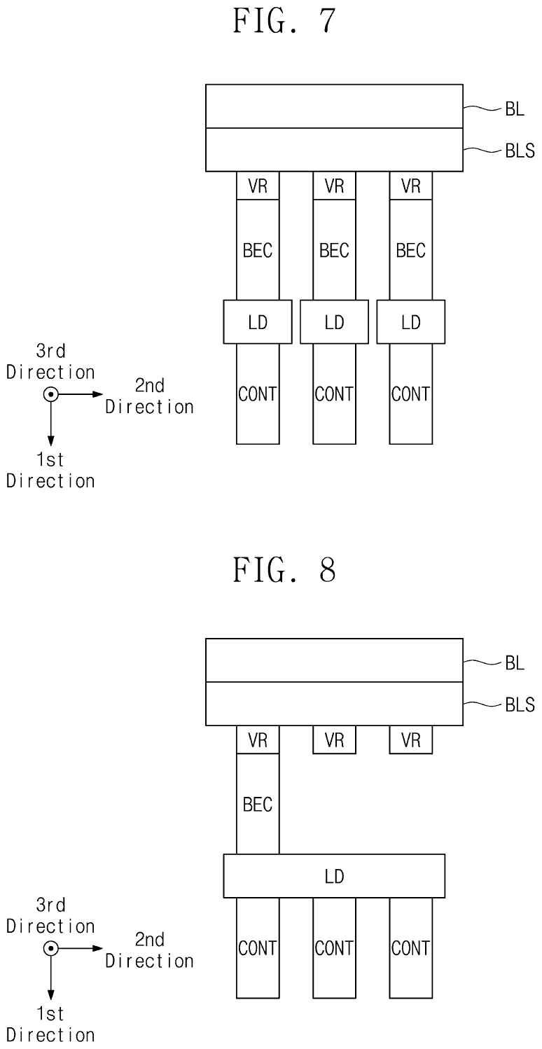

FIG. 7 illustrates an example of wires associated with the main memory cell MC. In some embodiments, a conductive material is illustrated in FIG. 7. Referring to FIGS. 3 and 7, the bit line BL (or the reference bit line RBL) extending in a second direction may be provided. A bit line stud BLS which extends along the second direction together with the bit line BL may be provided under the bit line BL (along a first direction).

Three variable resistance elements VR may be provided under the bit line stud BLS. The number of variable resistance elements VR provided under the bit line stud BLS is provided as an example for describing some embodiments of the present disclosure easily, and the present disclosure is not limited thereto.

Bottom electric contacts BEC may be respectively provided under the variable resistance elements VR (along the first direction). Landing LD may be respectively provided under the bottom electric contacts BEC (along the first direction). Contacts CONT may be respectively provided under the landings LD (along the first direction). The contacts CONT may be electrically connected to the second terminals of the selection elements SE. Structures of the selection elements SE and the source lines SL or RSL are omitted to prevent a drawing from being unnecessarily complicated.

FIG. 8 illustrates an example of wires associated with the OTP cell OC according to some embodiments of the present disclosure. Referring to FIGS. 5 and 8, the second terminals of the selection elements SE of the OTP cell OC may be connected in common. The landing LD integrally formed in FIG. 8 (compared to FIG. 7) may connect the second terminals of the selection elements SE of the OTP cell OC in common.

In the OTP cell OC, as two of three bottom electric contacts are removed, only one variable resistance element VR among three variable resistance elements VR may be electrically connected (physically or electrically) between the selection elements SE and the bit line BL.

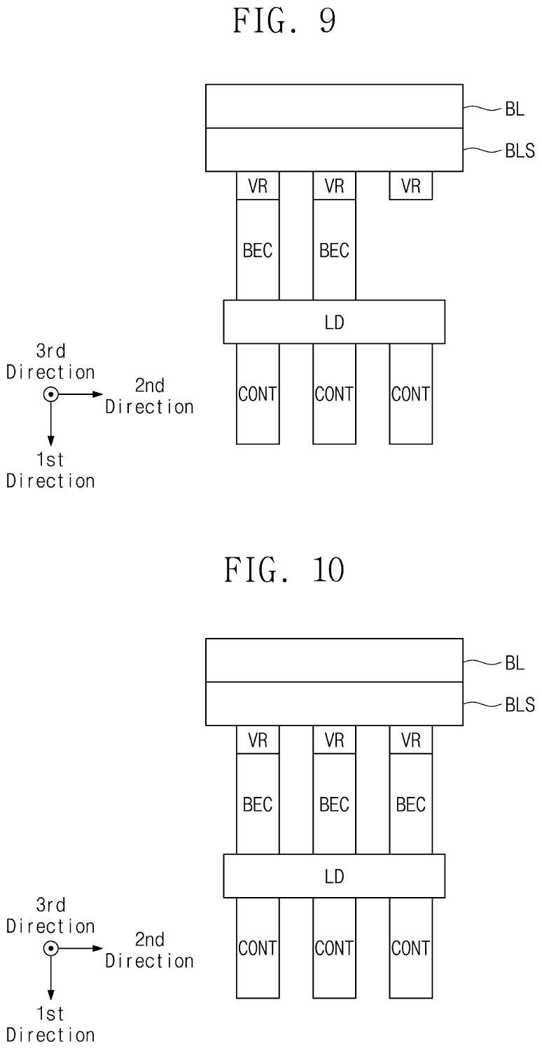

FIG. 9 illustrates an example of wires associated with the OTP reference cell ORC according to some embodiments of the present disclosure. Referring to FIGS. 5 and 9, the second terminals of the selection elements SE of the OTP reference cell ORC may be connected in common. The landing LD integrally formed in FIG. 9 (compared to FIG. 7) may connect the second terminals of the selection elements SE of the reference cell RC in common.

In the OTP reference cell ORC, as one of three bottom electric contacts is removed, only two variable resistance elements VR among three variable resistance elements VR may be connected (physically or electrically) between the selection elements SE and the bit line BL.

In some embodiments, when the OTP reference cell ORC is configured to provide a voltage or a current by using two variable resistance elements VR, the OTP reference cell ORC may be implemented as illustrated in FIG. 9.

FIG. 10 illustrates an example of wires associated with the OTP reference cell ORC according to some other embodiments of the present disclosure. Referring to FIGS. 5 and 10, the second terminals of the selection elements SE of the OTP reference cell ORC may be connected in common. The landing LD integrally formed in FIG. 10 (compared to FIG. 7) may connect the second terminals of the selection elements SE of the OTP reference cell ORC in common.

In the OTP reference cell ORC, as all of the three bottom electric contacts are not removed, all of the three variable resistance elements VR may be electrically connected (physically or electrically) between the selection elements SE and the bit line BL.

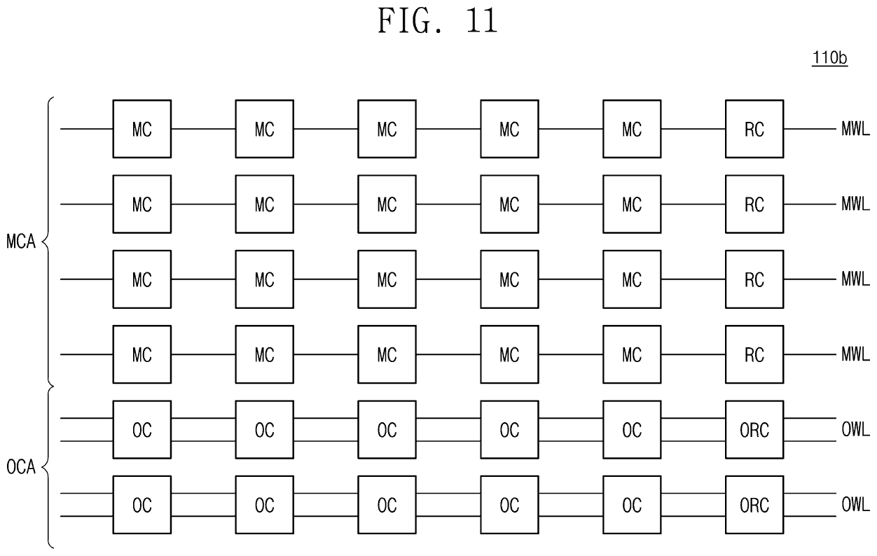

FIG. 11 illustrates a memory cell array 110b according to some embodiments of the present disclosure. Referring to FIGS. 1 and 11, the memory cell array 110b may include a main cell area MCA and an OTP cell area OCA. The main cell area MCA may include main memory cells MC and reference cells RC arranged in rows and columns. The main memory cells MC may be used to write data received from a host device or to read the written data. One row of main memory cells MC may be electrically connected to one main word line MWL.

The OTP cell area OCA may include OTP cells OC and OTP reference cells ORC arranged in rows and columns. The OTP cells OC may be cells which are permitted such that the write operation is performed only once and such that the read operation is performed plural times. The OTP cells OC may be used to store secure data such as a serial number of the nonvolatile memory device 100. In some embodiments, a resistance value of the OTP cell OC programmed once may be different from resistance values of the main memory cells MC.

The reference cell RC may be used to read the main memory cells MC of the main cell area MCA. A resistance value of the reference cell RC may be different from resistance values of the main memory cells MC. A resistance value of the OTP reference cell ORC may be different from resistance values of the main memory cells MC and resistance values of the OTP cells OC.

In some embodiments, the reference cell RC and the OTP reference cell ORC may be located at the same column. The OTP cells OC and the OTP reference cell ORC belonging to one row may be electrically connected to two OTP word lines OWL. However, the number of OTP word lines OWL electrically connected to the OTP cells OC the OTP reference cell ORC belonging to one row is plural, but the present disclosure is not limited thereto.

The first to m-th word lines WL1 to WLm described with reference to FIG. 1 may include the main word lines MWL and the OTP word lines OWL of FIG. 11.

In some embodiments, compared to FIG. 1, the first to n-th source lines SL1 to SLn and the first to n-th bit lines BL1 to BLn are omitted to prevent a drawing from being unnecessarily complicated. Memory cells which belong to one column and include the main memory cells MC, the OTP cells OC, the reference cell RC, or the OTP reference cell ORC of the memory cell array 110b may be connected in common to one source line and one bit line.

In some embodiments, the main memory cells MC and the reference cellc RC of the main cell area MCA may be implemented to be identical to those described with reference to FIG. 3.

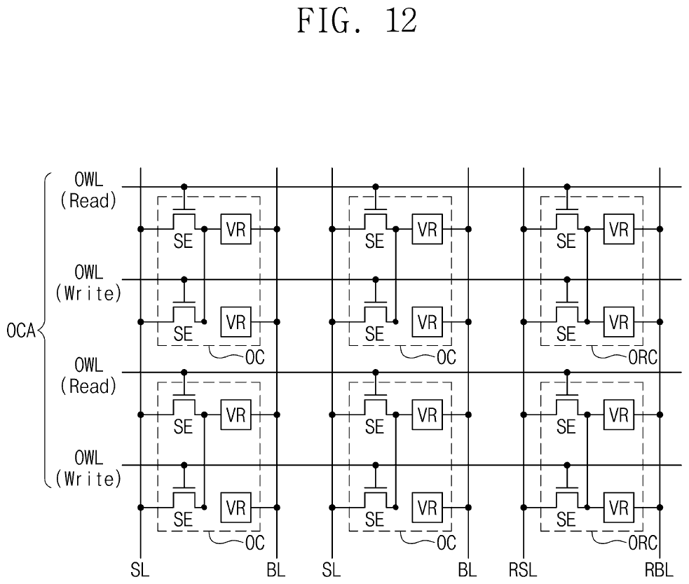

FIG. 12 illustrates an example of the OTP cell area OCA of FIG. 11. Referring to FIGS. 1, 11, and 12, each of the OTP cells OC may include two selection elements SE and two variable resistance elements VR. The selection element SE belonging to the first row of each OTP cell OC may include a first terminal electrically connected to a corresponding source line SL, a gate electrically connected to a corresponding OTP word line OWL, and a second terminal electrically connected to a corresponding variable resistance element VR. Each variable resistance element VR may be electrically connected to the second terminal of the corresponding selection element SE and a corresponding bit line BL (or the reference bit line RBL).

The row selection element SE belonging to the second row of each OTP cell OC may include a first terminal electrically connected to the corresponding source line SL, a gate electrically connected to a corresponding OTP word line OWL, and a second terminal floated. The variable resistance element VR belonging to the second row of each OTP cell OC may be electrically connected to the bit line BL.

The structure of the selection element SE and the variable resistance element VR of the first row of each OTP cell OC may be the same as or similar to the structure of the main memory cells MC. The structure of the selection element SE and the variable resistance element VR of the second row of each OTP cell OC may be the same as or similar to the structure of the main memory cells MC except that the selection element SE and the variable resistance element VR are not connected.

The OTP reference cell ORC may include two selection elements SE and two variable resistance elements VR. Each of the selection elements SE belonging to the first row and the second row of the OTP reference cell ORC may include a first terminal electrically connected to the reference source line RSL, a gate electrically connected to a corresponding OTP word line OWL, and a second terminal electrically connected to a corresponding variable resistance element VR. Each variable resistance element VR may be electrically connected to the second terminal of the corresponding selection element SE and the reference bit line RBL.

The structure of the selection element SE and the variable resistance element VR of each row of the OTP reference cell ORC may be the same as or similar to the structure of the main memory cell MC.

In some embodiments, an operation of the OTP cell area OCA may be similar to that described with reference to FIGS. 2 to 10 except that two selection elements SE and two variable resistance elements VR are included in each of one OTP cell OC, one reference cell RC, and one OTP reference cell ORC. Thus, additional description will be omitted to avoid redundancy.

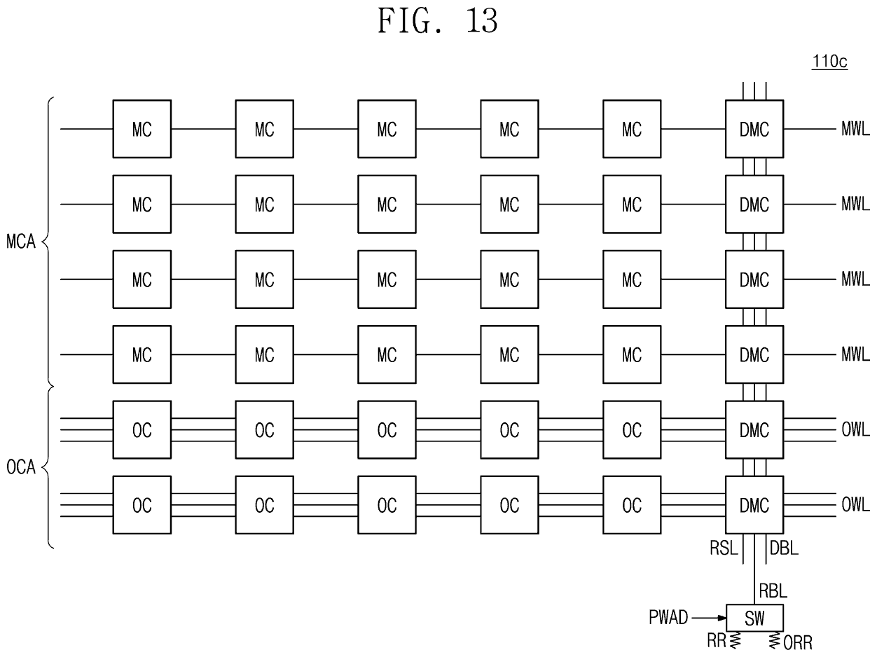

FIG. 13 illustrates a memory cell array 110c according to some embodiments of the present disclosure. Referring to FIGS. 1 and 13, the memory cell array 110c may include a main cell area MCA and an OTP cell area OCA. The main cell area MCA may include main memory cells MC arranged in rows and columns and dummy cells DMC arranged in the rows and one column. The main memory cells MC may be used to write data received from a host device or to read the written data. One row of main memory cells MC may be electrically connected to one main word line MWL. The dummy cells DMC may be similar in structure to the main memory cells MC but may not be used to store data. The dummy cells DMC may be used to provide an electrical path.

The OTP cell area OCA may include OTP cells OC arranged in rows and columns and dummy cells DMC arranged in the rows and one column. The OTP cells OC may be cells which are permitted such that the write operation is performed only once and such that the read operation is performed plural times. The OTP cells OC may be used to store secure data such as a serial number of the nonvolatile memory device 100. In some embodiments, a resistance value of the OTP cell OC programmed once may be different from resistance values of the main memory cells MC. The dummy cells DMC may be similar in structure to the main memory cells MC but may not be used to store data. The dummy cells DMC may be used to provide an electrical path.

The first to m-th word lines WL1 to WLm described with reference to FIG. 1 may include the main word lines MWL and the OTP word lines OWL of FIG. 13.

In some embodiments, compared to FIG. 1, the first to n-th source lines SL1 to SLn and the first to n-th bit lines BL1 to BLn are omitted to prevent a drawing from being unnecessarily complicated. Memory cells which belong to one column and include the main memory cells MC and the OTP cells OC of the memory cell array 110c may be connected in common to one source line and one bit line.

In some embodiments, the dummy cells DMC may be electrically connected to a dummy bit line DBL, a reference bit line RBL, and a reference source line RSL. The reference bit line RBL may be electrically connected to a switch SW. The switch SW may selectively connect one of a reference resistor RR and an OTP reference resistor ORR with the reference bit line RBL. For example, the switch SW may electrically connect one of the reference resistor RR and the OTP reference resistor ORR with the reference bit line RBL in response to a partial word line address PWAD.

The partial word line address PWAD may be extracted from the address ADDR received by the control logic 160 during the read operation. The control logic 160 may extract whether the address ADDR indicates any of the main cell area MCA and the OTP cell area OCA, as the partial word line address PWAD. The control logic 160 may provide the partial word line address PWAD to the switch SW.

The reference resistor RR may be used for the read operation of the main memory cells MC. When the partial word line address PWAD indicates the main cell area MCA, the switch SW may electrically connect the reference resistor RR with the reference bit line RBL. The reference resistor RR may have a resistance value between states of the main memory cells MC, for example, a resistance value corresponding to the reference state R_RC described with reference to FIG. 6.

The OTP reference resistor ORR may be used for the read operation of the OTP cells OC. When the partial word line address PWAD indicates the OTP cell area OCA, the switch SW may electrically connect the OTP reference resistor ORR with the reference bit line RBL. The OTP reference resistor ORR may have a resistance value between the second state R_S2 and the third state R_S3, for example, a resistance value corresponding to the OTP reference state R_ORC described with reference to FIG. 6.

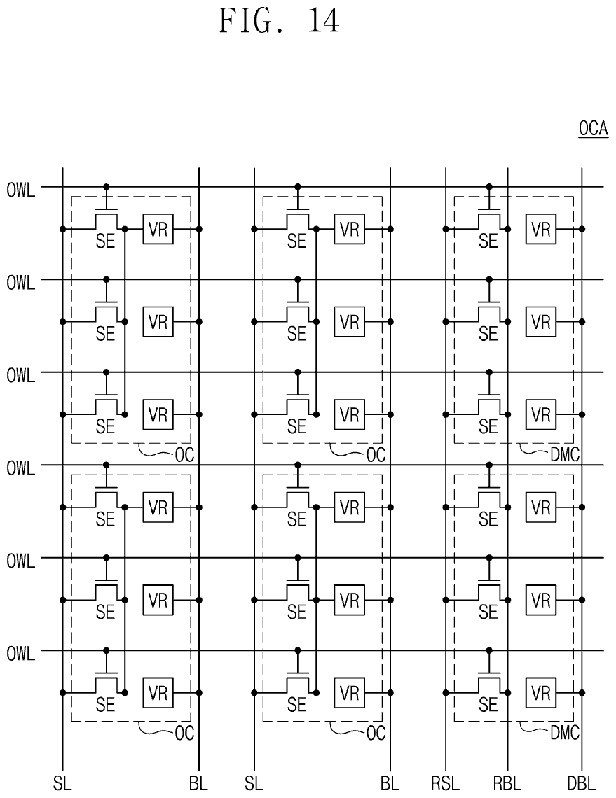

FIG. 14 illustrates an example of the OTP cell area OCA of FIG. 13. Referring to FIGS. 13 and 14, each of the OTP cells OC may include three selection elements SE and three variable resistance elements VR. The selection element SE belonging to the first row of each OTP cell OC may include a first terminal electrically connected to a corresponding source line SL, a gate electrically connected to a corresponding OTP word line OWL, and a second terminal electrically connected to a corresponding variable resistance element VR. Each variable resistance element VR may be electrically connected to the second terminal of the corresponding selection element SE and a corresponding bit line BL.

Each of the selection elements SE belonging to the second row and the third row of each OTP cell OC may include a first terminal electrically connected to the corresponding source line SL, a gate electrically connected to a corresponding OTP word line OWL, and a second terminal floated. The variable resistance elements VR belonging to the second row and the third row of each OTP cell OC may be electrically connected to the bit line BL.

The structure of the selection element SE and the variable resistance element VR of the first row of each OTP cell OC may be the same as or similar to the structure of the main memory cells MC. The structure of the selection element SE and the variable resistance element VR of each of the second row and the third row of each OTP cell OC may be the same as or similar to the structure of the main memory cells MC except that the selection element SE and the variable resistance element VR are not connected.

Each of the dummy cells DMC may include three selection elements SE and three variable resistance elements VR. Each of the selection elements SE belonging to the first row, the second row, and the third row of each dummy cell DMC may include a first terminal electrically connected to the reference source line RSL, a gate electrically connected to a corresponding OTP word line OWL, and a second terminal floated. Each of the variable resistance elements VR belonging to the first row, the second row, and the third row of each dummy cell DMC may be electrically connected to the dummy bit line DBL.

The structure of the selection element SE and the variable resistance element VR of each of the first row, the second row, and the third row of each dummy cell DMC may be the same as or similar to the structure of the main memory cells MC except that the selection element SE and the variable resistance element VR are not connected.

In the dummy cells DMC, because the selection elements SE are separated from the dummy bit line DBL, the dummy bit line DBL may have no influence on the operation of the dummy cells DMC.

The reference bit line RBL may be connected in common to the second terminals of the selection elements SE. The selection elements SE of the dummy cells DMC may be turned on or turned off between the reference source line RSL and the reference bit line RBL. Because the reference bit line RBL is electrically connected to the reference resistor RR or the OTP reference resistor ORR, a voltage or a current corresponding to the reference resistor RR or the OTP reference resistor ORR may be generated through the reference bit line RBL. That is, the read operation of the main memory cells MC and the read operation of the OTP cells OC may be selectively performed by selecting a resistor electrically connected to the reference bit line RBL.

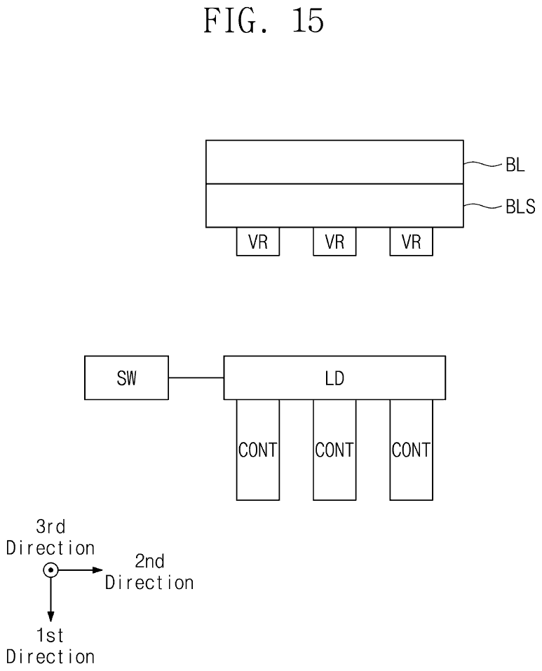

FIG. 15 illustrates an example of wires associated with the dummy cell DMC according to some embodiments of the present disclosure. Referring to FIGS. 14 and 15, the second terminals of the selection elements SE of the dummy cell DMC may be connected in common. A landing LD integrally formed in FIG. 15 (compared to FIG. 7) may electrically connect the second terminals of the selection elements SE of the dummy cell DMC in common. The reference bit line RBL may be provided by electrically connecting the landing LD with landings LD of the other dummy cells DMC, which extend along the first direction.

In the dummy cell DMC, as three bottom electric contacts are removed, the connection between the three variable resistance elements VR and the three selection elements SE may not be made. The switch SW may be electrically connected to the reference bit line RBL providing by using the landing LD.

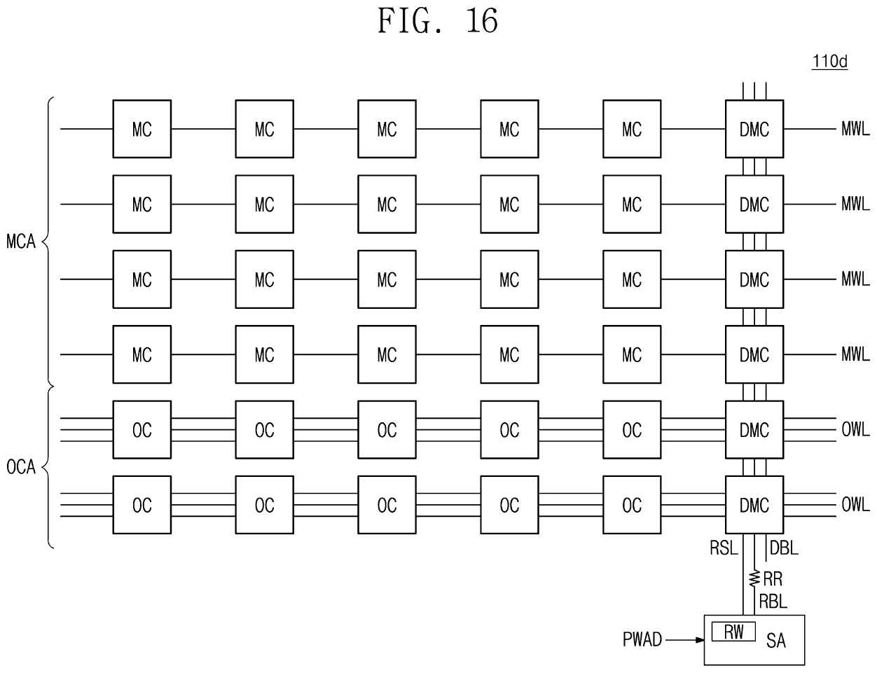

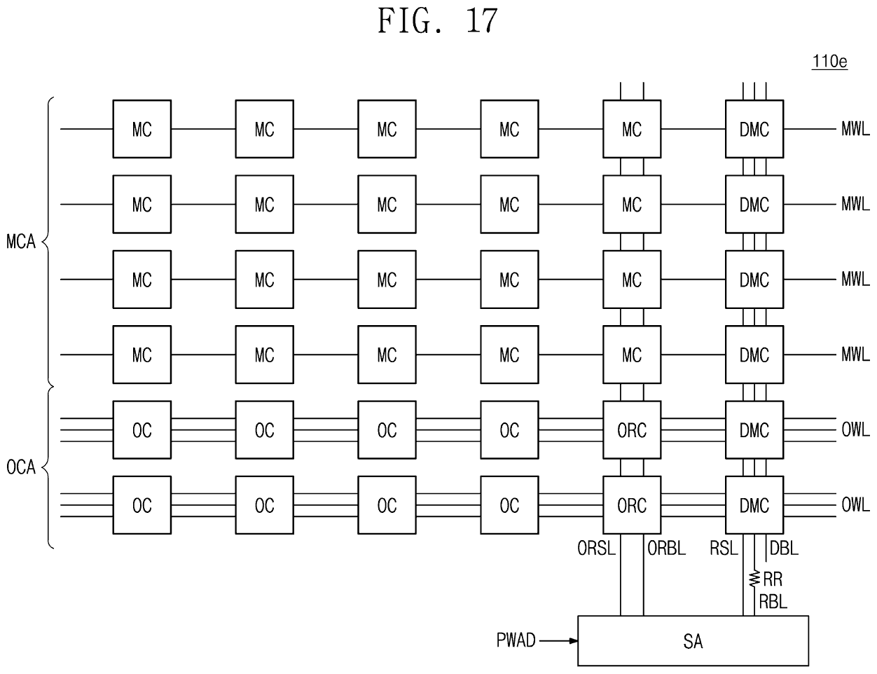

FIG. 16 illustrates a memory cell array 110d according to some embodiments of the present disclosure. Referring to FIGS. 1 and 16, the memory cell array 110d may include a main cell area MCA and an OTP cell area OCA. The main cell area MCA may include main memory cells MC arranged in rows and columns and dummy cells DMC arranged in the rows and one column. The main memory cells MC may be used to write data received from a host device or to read the written data. One row of main memory cells MC may be electrically connected to one main word line MWL. The dummy cells DMC may be similar in structure to the main memory cells MC but may not be used to store data. The dummy cells DMC may be used to provide an electrical path.

The OTP cell area OCA may include OTP cells OC arranged in rows and columns and dummy cells DMC arranged in the rows and one column. The OTP cells OC may be cells which are permitted such that the write operation is performed only once and such that the read operation is performed plural times. The OTP cells OC may be used to store secure data such as a serial number of the nonvolatile memory device 100. In some embodiments, a resistance value of the OTP cell OC programmed once may be different from resistance values of the main memory cells MC. The dummy cells DMC may be similar in structure to the main memory cells MC but may not be used to store data. The dummy cells DMC may be used to provide an electrical path.

The first to m-th word lines WL1 to WLm described with reference to FIG. 1 may include the main word lines MWL and the OTP word lines OWL of FIG. 16.

In some embodiments, compared to FIG. 1, the first to n-th source lines SL1 to SLn and the first to n-th bit lines BL1 to BLn are omitted to prevent a drawing from being unnecessarily complicated. Memory cells which belong to one column and include the main memory cells MC and the OTP cells OC of the memory cell array 110d may be connected in common to one source line and one bit line.

In some embodiments, the dummy cells DMC may be electrically connected to a dummy bit line DBL, a reference bit line RBL, and a reference source line RSL. The reference bit line RBL may be electrically connected to a corresponding sense amplifier circuit SA through a reference resistor RR. The sense amplifier circuit SA may include a read circuit RW. During the read operation, the read circuit RW may adjust a voltage or a current to be applied to the reference bit line RBL or the reference source line RSL in response to a partial word line address PWAD.

The partial word line address PWAD may be extracted from the address ADDR received by the control logic 160 during the read operation. The control logic 160 may extract whether the address ADDR indicates any of the main cell area MCA and the OTP cell area OCA, as the partial word line address PWAD. The control logic 160 may provide the partial word line address PWAD to the read circuit RW.

The reference resistor RR may be used for the read operation of the main memory cells MC and the OTP cells OC. When the partial word line address PWAD indicates the main cell area MCA, the read circuit RW may supply a voltage or a current suitable for the read operation of the main memory cell MC to the reference bit line RBL or the reference source line RSL.

When the partial word line address PWAD indicates the OTP cell area OCA, the read circuit RW may supply a voltage or a current suitable for the read operation of the OTP cell OC to the reference bit line RBL or the reference source line RSL.

FIG. 17 illustrates a memory cell array 110e according to some embodiments of the present disclosure. Referring to FIGS. 1 and 17, the memory cell array 110e may include a main cell area MCA and an OTP cell area OCA. The main cell area MCA may include main memory cells MC arranged in rows and columns and dummy cells DMC arranged in the rows and one column. The main memory cells MC may be used to write data received from a host device or to read the written data. One row of main memory cells MC may be electrically connected to one main word line MWL. The dummy cells DMC may be similar in structure to the main memory cells MC but may not be used to store data. The dummy cells DMC may be used to provide an electrical path.

The OTP cell area OCA may include OTP cells OC arranged in rows and columns and dummy cells DMC arranged in the rows and one column, and OTP reference cells ORC. The OTP cells OC may be cells which are permitted such that the write operation is performed only once and such that the read operation is performed plural times. The OTP cells OC may be used to store secure data such as a serial number of the nonvolatile memory device 100. In some embodiments, a resistance value of the OTP cell OC programmed once may be different from resistance values of the main memory cells MC.

The dummy cells DMC may be similar in structure to the main memory cells MC but may not be used to store data. The dummy cells DMC may be used to provide an electrical path. The dummy cells DMC may be electrically connected to a dummy bit line DBL, a reference bit line RBL, and a reference source line RSL. The dummy cells DMC may be implemented as described with reference to FIG. 14.

The OTP reference cells ORC may be electrically connected to an OTP reference bit line ORBL and an OTP reference source line ORSL. The OTP reference cell ORC may be implemented as described with reference to FIG. 5.

The first to m-th word lines WL1 to WLm described with reference to FIG. 1 may include the main word lines MWL and the OTP word lines OWL of FIG. 17.

In some embodiments, compared to FIG. 1, the first to n-th source lines SL1 to SLn and the first to n-th bit lines BL1 to BLn are omitted to prevent a drawing from being unnecessarily complicated. Memory cells which belong to one column and include the main memory cells MC and the OTP cells OC of the memory cell array 100e may be electrically connected in common to one source line and one bit line.

In some embodiments, the dummy bit line DBL, the reference bit line RBL, and the reference source line RSL electrically connected to the dummy cells DMC may be electrically connected to the sense amplifier circuit SA. The reference bit line RBL may be electrically connected to the corresponding sense amplifier circuit SA through a reference resistor RR. During the read operation of the main memory cells MC, the sense amplifier circuit SA may read the main memory cells MC by using the reference resistor RR and a read voltage or current. The reference resistor RR may have a resistance value corresponding to the reference state R_RC of FIG. 6.

The OTP reference bit line ORBL and the OTP reference source line ORSL electrically connected to the OTP reference cells ORC may be electrically connected to the sense amplifier circuit SA. During the read operation of the OTP cells OC, the sense amplifier circuit SA may read the OTP cells OC by using the OTP reference cell ORC and a read voltage or current. The OTP reference cell ORC may have a resistance value corresponding to the OTP reference state R_ORC of FIG. 6.

In some embodiments, the read voltage or current used during the read operation of the main memory cells MC may be the same as or similar to the read voltage or current used during the read operation of the OTP cell OC.

The sense amplifier circuit SA may use the reference resistor RR during the read operation of the main memory cells MC and may use the OTP reference cell ORC during the read operation of the OTP cells OC. For example, the sense amplifier circuit SA may identify the read operation of the main memory cells MC or the read operation of the OTP cells OC in response to a partial word line address PWAD.

The partial word line address PWAD may be extracted from the address ADDR received by the control logic 160 during the read operation. The control logic 160 may extract whether the address ADDR indicates any of the main cell area MCA and the OTP cell area OCA, as the partial word line address PWAD. The control logic 160 may provide the partial word line address PWAD to the read circuit RW.

As described above, the nonvolatile memory device 100 may be implemented by combining various embodiments such as the reference cell RC, the OTP reference cell ORC, the reference resistor RR, the OTP reference resistor ORR, the dummy cell DMC, the switch SW, and the read circuit RW.

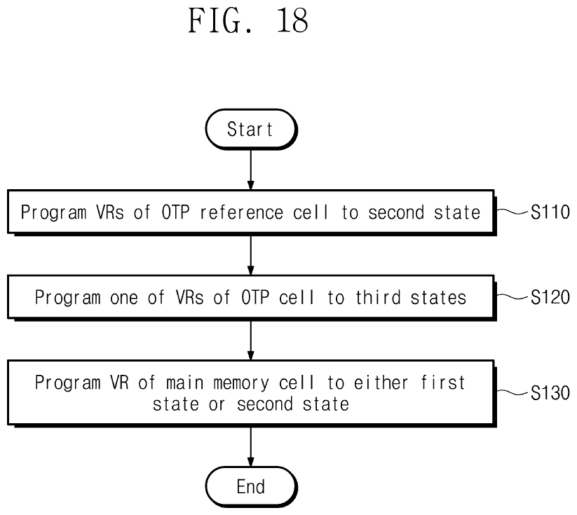

FIG. 18 illustrates an operating method of the nonvolatile memory device 100 according to some embodiments of the present disclosure. Referring to FIGS. 1, 6, and 18, in operation S110, the nonvolatile memory device 100 may program the variable resistance elements VR of the OTP reference cell ORC to the second state R_S2.

In operation S120, the nonvolatile memory device 100 may program one of the variable resistance elements VR of the OTP cell OC to the third state R_S3.

In operation S130, the nonvolatile memory device 100 may program the variable resistance element VR of the main memory cell MC to either a first state or a second state.

The variable resistance elements VR of the OTP reference cell ORC may be programmed to one of the states of the variable resistance element VR of the main memory cell MC, but the OTP reference cell ORC may be used to distinguish states of the OTP cell OC and the main memory cell MC.

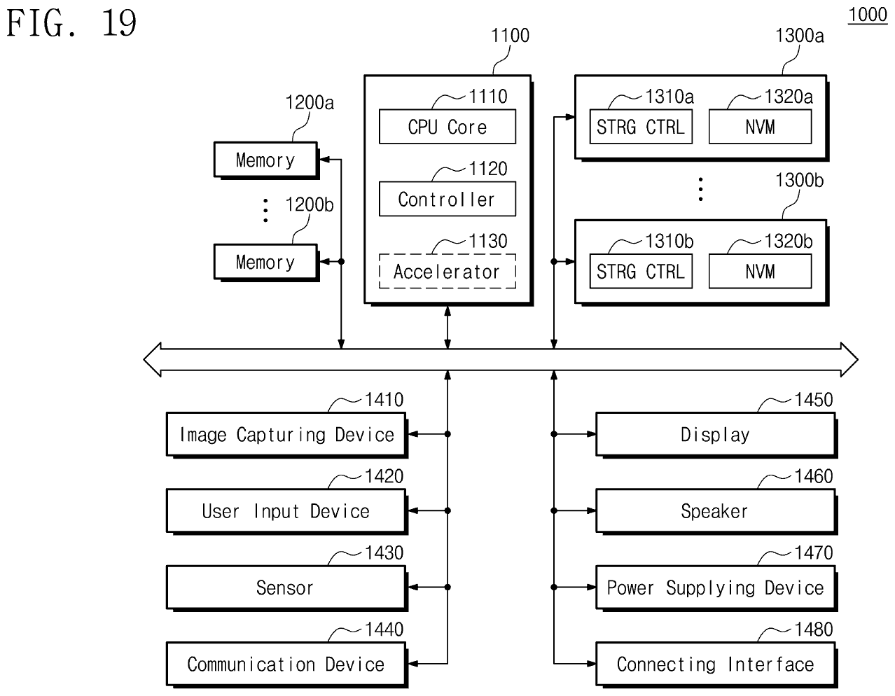

FIG. 19 is a diagram of a system 1000 to which a storage device is applied, according to some embodiments. The system 1000 of FIG. 19 may basically be a mobile system, such as a portable communication terminal (e.g., a mobile phone), a smartphone, a tablet personal computer (PC), a wearable device, a healthcare device, or an Internet of things (IoT) device. However, the system 1000 of FIG. 19 is not necessarily limited to the mobile system and may be a PC, a laptop computer, a server, a media player, or an automotive device (e.g., a navigation device).

Referring to FIG. 19, the system 1000 may include a main processor 1100, memories (e.g., 1200a and 1200b), and storage devices (e.g., 1300a and 1300b). In addition, the system 1000 may include at least one of an image capturing device 1410, a user input device 1420, a sensor 1430, a communication device 1440, a display 1450, a speaker 1460, a power supplying device 1470, and a connecting interface 1480.

The main processor 1100 may control operations of the system 1000, and more specifically, operations of other components included in the system 1000. The main processor 1100 may be implemented as a general-purpose processor, a dedicated processor, or an application processor.

The main processor 1100 may include at least one CPU core 1110 and further include a controller 1120 configured to control the memories 1200a and 1200b and/or the storage devices 1300a and 1300b. In some embodiments, the main processor 1100 may further include an accelerator 1130, which is a dedicated circuit for a high-speed data operation, such as an artificial intelligence (AI) data operation. The accelerator 1130 may include a graphics processing unit (GPU), a neural processing unit (NPU) and/or a data processing unit (DPU) and be implemented as a chip that is physically separate from the other components of the main processor 1100.

The memories 1200a and 1200b may be used as main memory devices of the system 1000. Although each of the memories 1200a and 1200b may include a volatile memory, such as static random access memory (SRAM) and/or dynamic RAM (DRAM), each of the memories 1200a and 1200b may include non-volatile memory, such as a flash memory, phase-change RAM (PRAM) and/or resistive RAM (RRAM). The memories 1200a and 1200b may be implemented in the same package as the main processor 1100.

The storage devices 1300a and 1300b may serve as non-volatile storage devices configured to store data regardless of whether power is supplied thereto, and have larger storage capacity than the memories 1200a and 1200b. The storage devices 1300a and 1300b may respectively include storage controllers (STRG CTRL) 1310a and 1310b and NVM (Non-Volatile Memory) s 1320a and 1320b configured to store data via the control of the storage controllers 1310a and 1310b. Although the NVMs 1320a and 1320b may include flash memories having a two-dimensional (2D) structure or a three-dimensional (3D) V-NAND structure, the NVMs 1320a and 1320b may include other types of NVMs, such as PRAM and/or RRAM.

The storage devices 1300a and 1300b may be physically separated from the main processor 1100 and included in the system 1000 or implemented in the same package as the main processor 1100. In addition, the storage devices 1300a and 1300b may have types of solid-state devices (SSDs) or memory cards and be removably combined with other components of the system 100 through an interface, such as the connecting interface 1480 that will be described below. The storage devices 1300a and 1300b may be devices to which a standard protocol, such as a universal flash storage (UFS), an embedded multi-media card (eMMC), or a non-volatile memory express (NVMe), is applied, without being limited thereto.

The image capturing device 1410 may capture still images or moving images. The image capturing device 1410 may include a camera, a camcorder, and/or a webcam.

The user input device 1420 may receive various types of data input by a user of the system 1000 and include a touch pad, a keypad, a keyboard, a mouse, and/or a microphone.

The sensor 1430 may detect various types of physical quantities, which may be obtained from the outside of the system 1000, and convert the detected physical quantities into electric signals. The sensor 1430 may include a temperature sensor, a pressure sensor, an illuminance sensor, a position sensor, an acceleration sensor, a biosensor, and/or a gyroscope sensor.

The communication device 1440 may transmit and receive signals between other devices outside the system 1000 according to various communication protocols. The communication device 1440 may include an antenna, a transceiver, and/or a modem.

The display 1450 and the speaker 1460 may serve as output devices configured to respectively output visual information and auditory information to the user of the system 1000.

The power supplying device 1470 may appropriately convert power supplied from a battery (not shown) embedded in the system 1000 and/or an external power source, and supply the converted power to each of components of the system 1000.

The connecting interface 1480 may provide communication connection between the system 1000 and an external device, which is electrically connected to the system 1000 and capable of transmitting and receiving data to and from the system 1000. The connecting interface 1480 may be implemented by using various interface schemes, such as advanced technology attachment (ATA), serial ATA (SATA), external SATA (e-SATA), small computer small interface (SCSI), serial attached SCSI (SAS), peripheral component interconnection (PCI), PCI express (PCIe), NVMe, IEEE 1394, a universal serial bus (USB) interface, a secure digital (SD) card interface, a multi-media card (MMC) interface, an eMMC interface, a UFS interface, an embedded UFS (eUFS) interface, and a compact flash (CF) card interface.

In some embodiments, the nonvolatile memory device 100 described with reference to FIGS. 1 to 18 may be implemented with the nonvolatile memory devices 1320a and 1320b of the storage devices 1300a and 1300b. In some embodiments, the nonvolatile memory device 100 may be implemented with the memories 1200a and 1200b. The nonvolatile memories 1320a and 1320b or the memories 1200a and 1200b may be implemented by combining various embodiments such as the reference cell RC, the OTP reference cell ORC, the reference resistor RR, the OTP reference resistor ORR, the dummy cell DMC, the switch SW, and the read circuit RW.

In the above embodiments, components according to the present disclosure are described by using the terms “first”, “second”, “third”, etc. However, the terms “first”, “second”, “third”, etc. may be used to distinguish components from each other and do not limit the present disclosure. For example, the terms “first”, “second”, “third”, etc. do not involve an order or a numerical meaning of any form.

In the above embodiments, components according to embodiments of the present disclosure are referenced by using blocks. The blocks may be implemented with various hardware devices, such as an integrated circuit, an application specific IC (ASIC), a field programmable gate array (FPGA), and a complex programmable logic device (CPLD), firmware driven in hardware devices, software such as an application, or a combination of a hardware device and software. Also, the blocks may include circuits implemented with semiconductor elements in an integrated circuit, or circuits enrolled as an intellectual property (IP).

According to embodiments of the present disclosure, an OTP cell array is implemented in a partial area of a memory cell array of a nonvolatile memory device, and it is possible to program and read a memory cell and an OTP cell. Accordingly, a nonvolatile memory device capable of reducing power consumption with the reduced area is provided.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A memory device comprising:
a plurality of memory cells;
word lines electrically connected to rows of the plurality of memory cells; and
bit lines and source lines electrically connected with columns of the plurality of memory cells,
wherein the plurality of memory cells comprise:
main memory cells of a main cell area that are configured to support a read operation and a write operation;
one time program cells of a one time program (OTP) cell area that are each configured to support the write operation once; and
a one time program reference cell for the read operation of the one time program cells,
wherein each of the main memory cells is electrically connected to a respective word line of the word lines, and
wherein each of the one time program cells is electrically connected to at least two respective word lines of the word lines.

2. The memory device of claim 1, wherein a first word line among the at least two respective word lines is used for the write operation of the one time program cells, and
wherein a second word line among the at least two word lines is used for the read operation of the one time program cells.

3. The memory device of claim 1, wherein a first word line among the at least two respective word lines is used for the write operation of the one time program reference cell, and
wherein a second word line among the at least two respective word lines is used for the read operation of the one time program reference cell.

4. The memory device of claim 1, wherein each of the one time program cells includes at least two selection elements and at least two variable resistance elements, and
wherein ones of the at least two variable resistance elements are electrically isolated from the at least two selection elements.

5. The memory device of claim 4, wherein respective terminals of the at least two selection elements are electrically connected.

6. The memory device of claim 1, wherein the one time program reference cell includes at least two selection elements and at least two variable resistance elements, and
wherein respective terminals of the at least two selection elements are electrically connected.

7. The memory device of claim 1, wherein each of the one time program cells includes at least two selection elements and at least two variable resistance elements, and
wherein ones of the at least two selection elements are electrically connected to one of the source lines.

8. The memory device of claim 1, wherein the one time program reference cell includes at least two selection elements and at least two variable resistance elements, and
wherein respective terminals of the at least two selection elements are electrically connected one of the bit lines.

9. The memory device of claim 1, wherein the main memory cells are configured to be programmed to one of a first state having a first resistance value or a second state having a second resistance value that is less than the first resistance value,
wherein each of the one time program cells is configured to be programmed to a third state having a third resistance value that is less than the second resistance value, and
wherein the one time program reference cell is configured to be programmed to a fourth resistance value between the second resistance value and the third resistance value.

10. The memory device of claim 9, wherein each of the main memory cells includes one variable resistance element configured to be programmed to one of the first state or the second state,
wherein the one time program cell includes at least two first variable resistance elements,
wherein one of the at least two first variable resistance elements is configured to be programmed to the third state,
wherein the one time program reference cell includes at least two second variable resistance elements, and
wherein one of the at least two second variable resistance elements is configured to be programmed to the second state.

11. The memory device of claim 1, wherein the plurality of memory cells further comprises a reference cell of the main cell area for the read operation of the main memory cells, and
wherein the reference cell is electrically connected to the respective word line.

12. The memory device of claim 11, wherein the reference cell includes a selection element and a variable resistance element.

13. The memory device of claim 12,
wherein the selection element are electrically connected to one of the bit lines.

14. The memory device of claim 11, wherein the main memory cells are configured to be programmed to one of a first state having a first resistance value or a second state having a second resistance value that is less than the first resistance value,
wherein each of the one time program cells is configured to be programmed to a third state having a third resistance value that is less than the second resistance value, and
wherein the reference cell is configured to be programmed to a fourth state having a fourth resistance value between the second resistance value and the third resistance value.

15. The memory device of claim 14, wherein each of the main memory cells includes one variable resistance element configured to be programmed to one of the first state or the second state,
wherein the one time program cell includes at least two first variable resistance elements,
wherein one of the at least two first variable resistance elements is configured to be programmed to the third state,
wherein the reference cell includes one variable resistance element configured to be programmed to one of the fourth state.

16. The memory device of claim 1, further comprising:
a reference resistor having a fixed resistance value for the read operation of the main memory cells.

17. A memory device comprising:
a plurality of memory cells;
word lines electrically connected to rows of the plurality of memory cells; and
bit lines and source lines electrically connected with columns of the plurality of memory cells,
wherein the plurality of memory cells comprise:
main memory cells of a main cell area that are configured to support a read operation and a write operation;
one time program cells of a one time program (OTP) cell area that are configured to support the write operation once and the read operation;
a reference resistor electrically connected to a reference bit line and having a fixed resistance value for the read operation of the main memory cells and the one time program cells; and
a sense amplifier configured to apply a first voltage to a reference source line during the read operation of the main memory cells and configured to apply a second voltage different from the first voltage to the reference source line during the read operation of the one time program cells.

18. The memory device of claim 17, wherein each of the one time program cells comprises:
variable resistance elements on a side of a corresponding bit line among the bit lines;
a wire provided on an opposite side of the variable resistance elements from the variable resistance elements and electrically connected to a corresponding word line among the word lines; and
a contact electrically connecting one of the variable resistance elements with the wire.

19. The memory device of claim 18, wherein the reference resistor is electrically connected to the wire corresponding to the reference bit line.

20. A memory device comprising:
a plurality of memory cells;
word lines electrically connected to rows of the plurality of memory cells; and
bit lines and source lines electrically connected with columns of the plurality of memory cells,
wherein the plurality of memory cells comprise:
main memory cells of a main cell area that are configured to support a read operation and a write operation;
one time program cells of a one time program (OTP) cell area that are configured to support the write operation once and the read operation;
a reference resistor having a fixed first resistance value for the read operation of the main memory cells;
a one time program reference resistor having a fixed second resistance value for the read operation of the one time program cells; and
a switch configured to electrically connect the reference resistor to a reference bit line during the read operation of the main memory cells and to electrically connect the one time program reference resistor to the reference bit line during the read operation of the one time program cells.
